(19) United States
(12) Patent Application Publication
(10) Pub. No.: US 2016/0351526 A1
(43) Pub. Date: Dec. 1, 2016

(54) INTEGRATED CIRCUIT CHIP ATTACHMENT USING LOCAL HEAT SOURCE

(71) Applicant: Intel Corporation, Santa Clara, CA (US)

(72) Inventors: Thomas Alan Boyd, North Plains, OR (US); Daniel Edward Shier, Olympia, WA (US); Viktor Vogman, Olympia, WA (US); Jonathan William Thibado, Beaverton, OR (US); Joshua David Heppner, Chandler, AZ (US)

(73) Assignee: Intel Corporation, Santa Clara, CA (US)

(21) Appl. No.: 15/117,500

(22) PCT Filed: Mar. 29, 2014
(86) PCT No.: PCT/US2014/032280

§ 371 Date: Aug. 9, 2016

(51) Int. Cl. H01L 23/00

(52) U.S. Cl. CPC H01L 24/75; H01L 24/81; H01L 2224/75253; H01L 2224/75901; H01L 2224/81815; H01L 2224/81908

(57) ABSTRACT

Integrated circuit chip attachment is described using a local heat source. In one example an interposer has a top side to connect to a silicon component and a bottom side to connect to a circuit board, the top side having a plurality of contact pads to electrically connect to the silicon component using solder. The interposer a plurality of heater traces having connection terminals. A removable control module attaches over the interposer and silicon component to conduct a current to the heater connection terminals to heat the heater traces, to melt a solder on the contact pads of the interposer and to form a solder joint between the component and the interposer.

### FIELD

The present description relates to integrated circuit attachment to an external board or socket and, in particular, to attachment using a local heat source.

### BACKGROUND

Silicon chip components such as CPU's (Central Processing Units), GPU's (Graphics Processing Units), controllers, etc. use an interconnect interface between the pads on a surface of the component and a connection array on an external connector, such as a main circuit board, a test board, or a socket. The connection is typically accomplished by soldering in the case of a BGA (Ball Grid Array) through a socket in the case of an LGA (Land Grid Array). In a test platform environment, the interconnection is sometimes accomplished using a MPI (Metal Particle Interconnect) socket. During production, the component may be connected to several different test fixtures as it moves through different test scenarios before it is finally released. In addition, each circuit board or socket may be reused several times to test different components as the components move through the different test stages.

The different common connection systems provide particular characteristics that work well for different applications. BGA connections in which solder attaches the component are very reliable and provide good high speed signaling performance. However, the soldering is done in a controlled factory setting. Rework of the solder connections requires the controlled factory setting with specialized equipment and training.

LGA connections provide great flexibility. A component may be fitted in a socket at any point of the manufacturing process, and easily replaced in the field. However, the contacts in an LGA socket are prone to damage, rendering an expensive printed circuit board non-functional. In addition, the socket reduces high speed signal performance. The contacts and the paths through the socket add significant impedance and cross talk to the signals. The additional impedance contributes to significant power loss in the contact, thereby lowering power efficiency.

MPI sockets are expensive, and not suited for high volume production. The connections are subject to open contacts, high impedance, and may be unreliable when used for test equipment.

### DETAILED DESCRIPTION OF THE DRAWING FIGURES

Embodiments of the invention are illustrated by way of example, and not by way of limitation, in the figures of the accompanying drawings in which like reference numerals refer to similar elements.

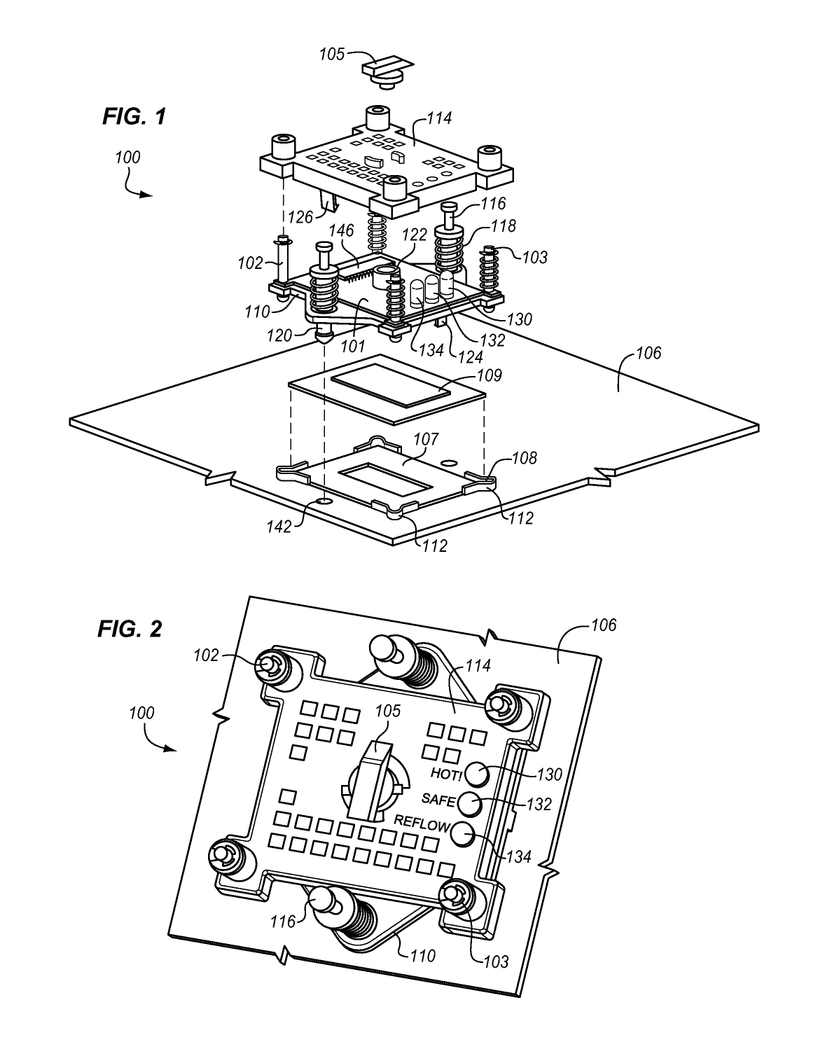

FIG. 1 is an isometric exploded diagram of a control module and circuit board according to an embodiment.

FIG. 2 is an isometric assembled diagram of the control module and circuit board of FIG. 1 according to an embodiment.

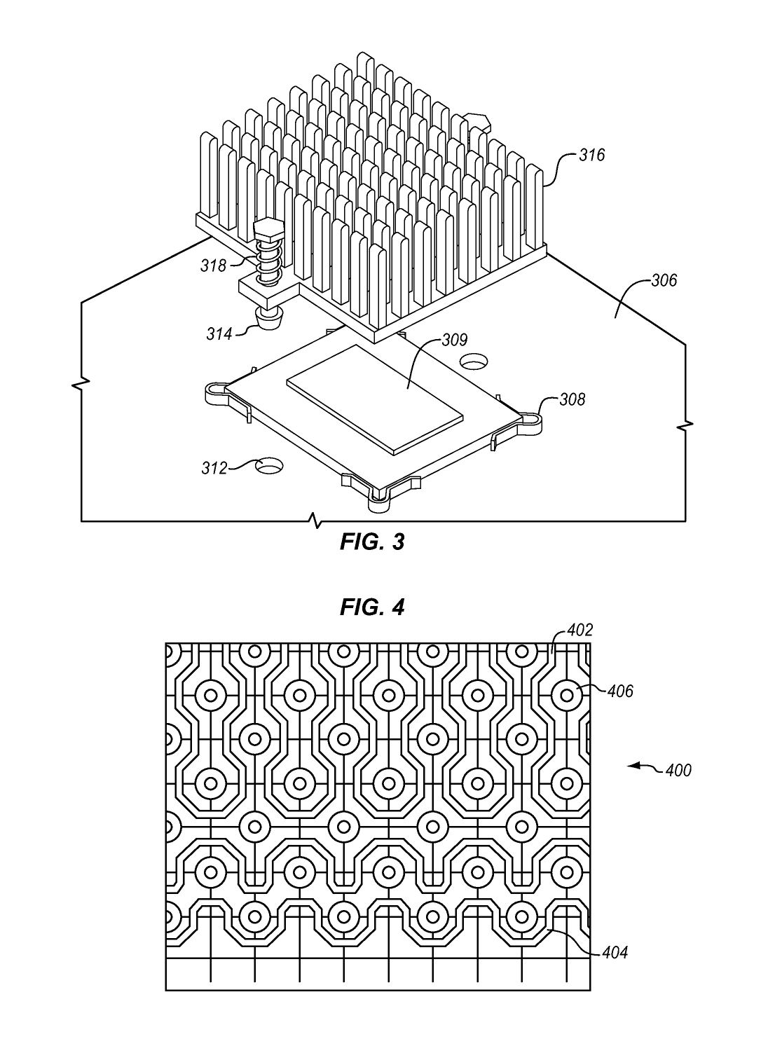

FIG. 3 is an isometric exploded diagram of attaching a heat sink to a circuit board according to an embodiment.

FIG. 4 is a top elevation view of a heater trace layer of an interposer according to an embodiment.

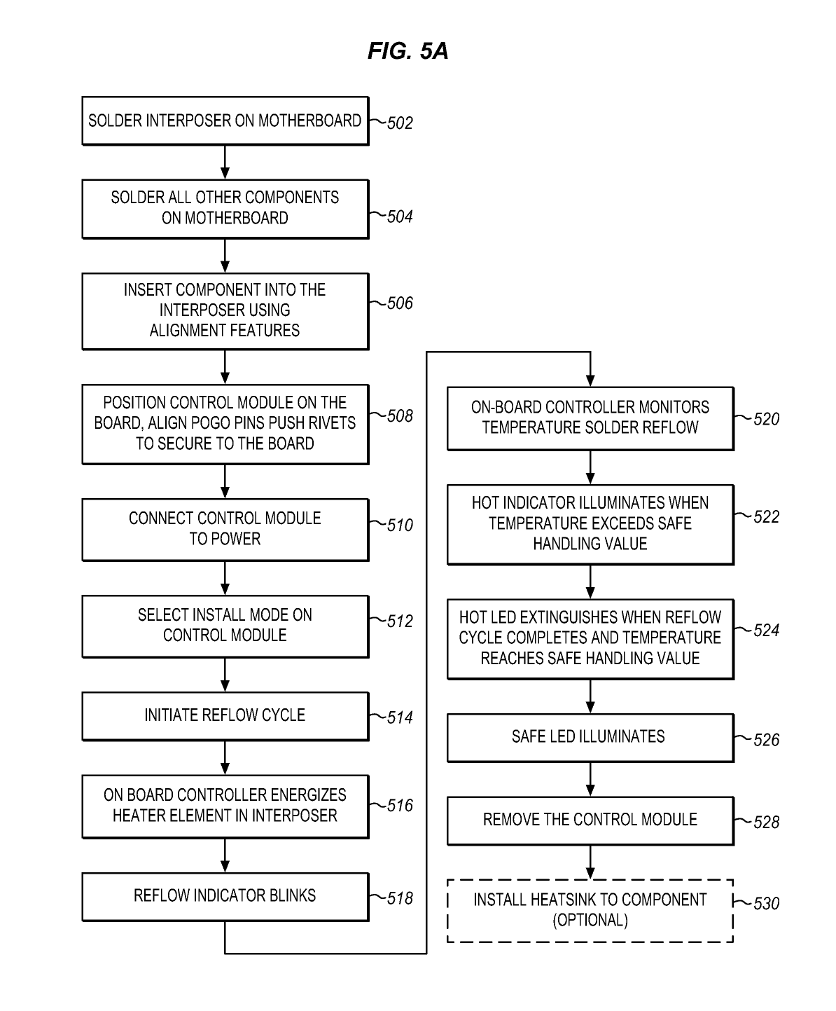

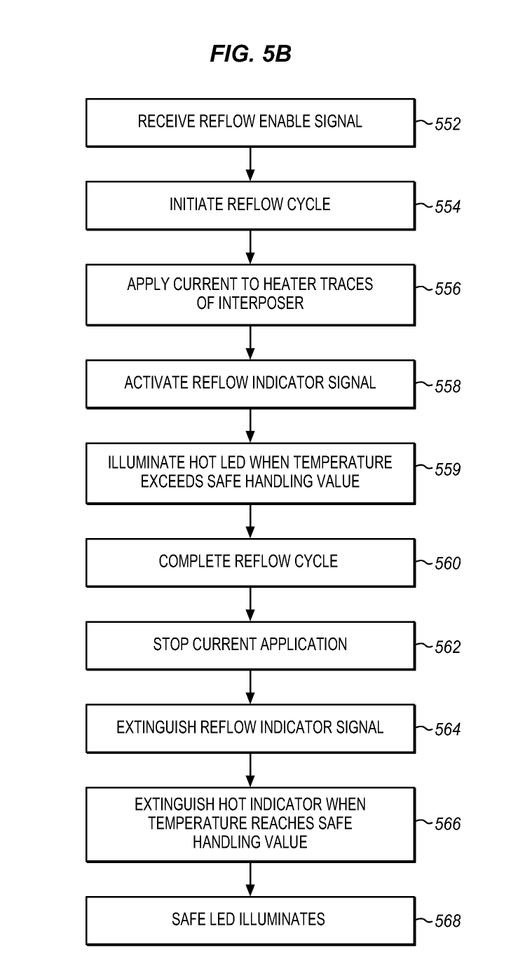

FIG. 5A is a process flow diagram of installing a silicon component on a circuit board according to an embodiment.

FIG. 5B is a process flow diagram of control module operations of installing a silicon component on a circuit board according to an embodiment.

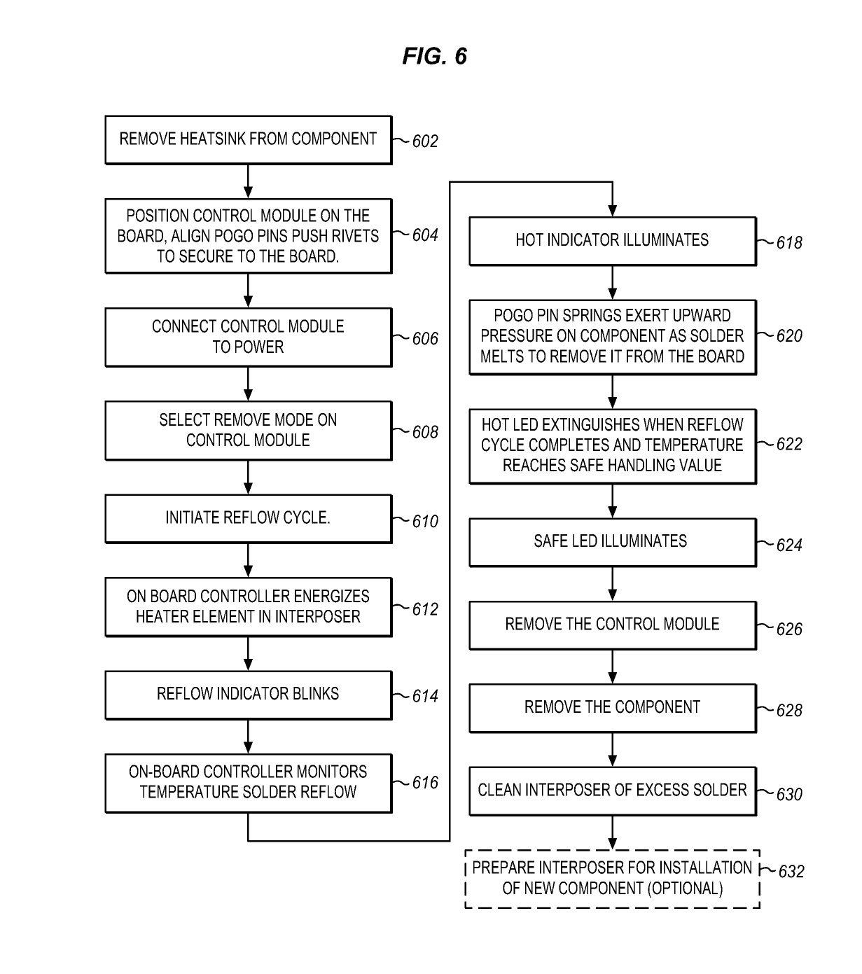

FIG. 6 is a process flow diagram of removing a silicon component from a circuit board according to an embodiment.

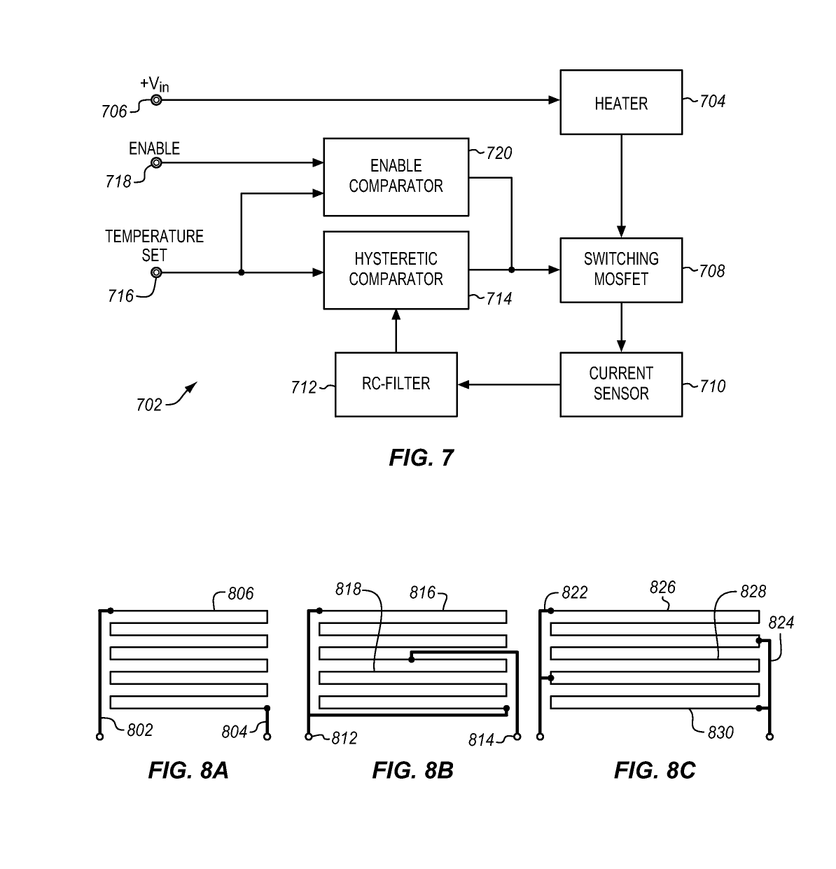

FIG. 7 is a block diagram of a heater temperature control circuit according to an embodiment.

FIG. 8A is a diagram of a resistive heater trace with one heater element according to an embodiment.

FIG. 8B is a diagram of a resistive heater trace with two heater elements according to an embodiment.

FIG. 8C is a diagram of a resistive heater trace with three heater elements according to an embodiment.

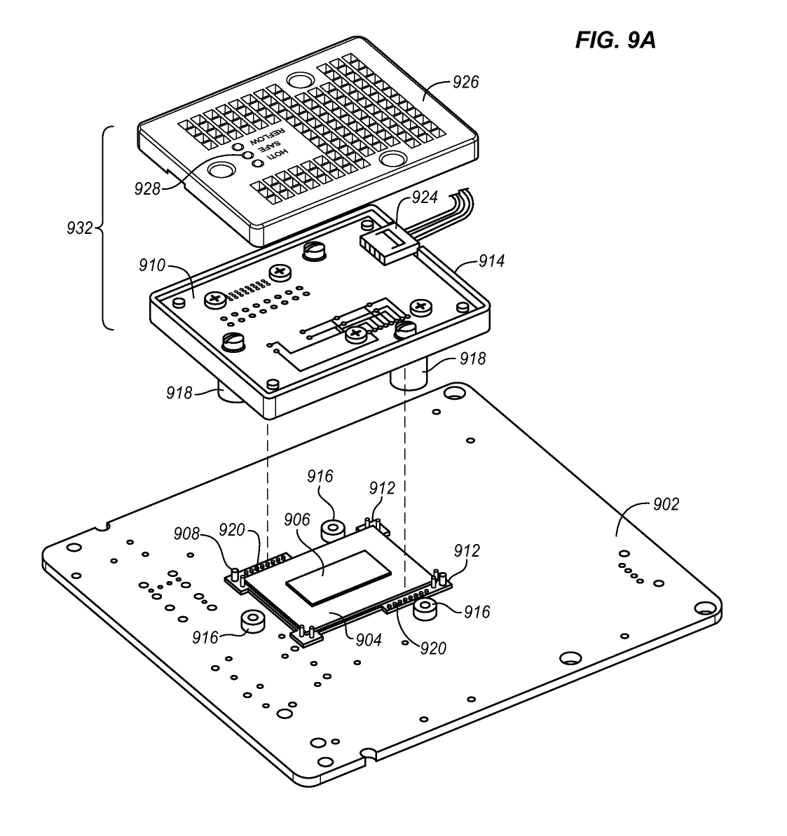

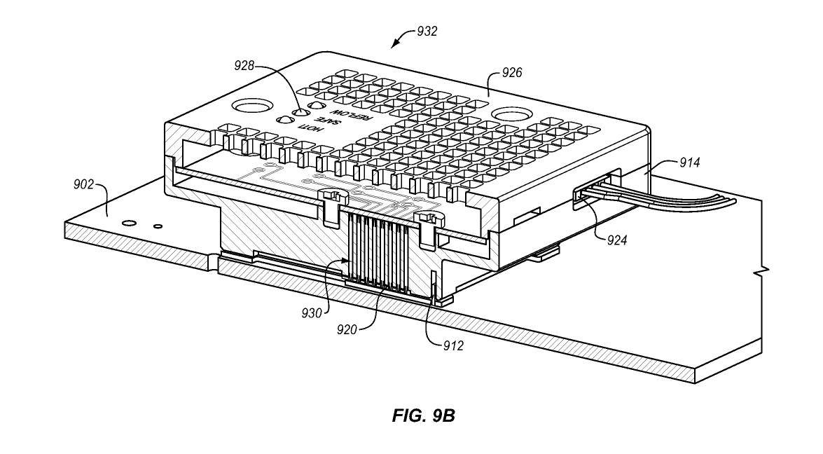

FIG. 9A is an isometric exploded diagram of an alternative control module and circuit board according to an embodiment.

FIG. 9B is an isometric assembled diagram of the control module in partial cross-section and circuit board of FIG. 9A according to an embodiment.

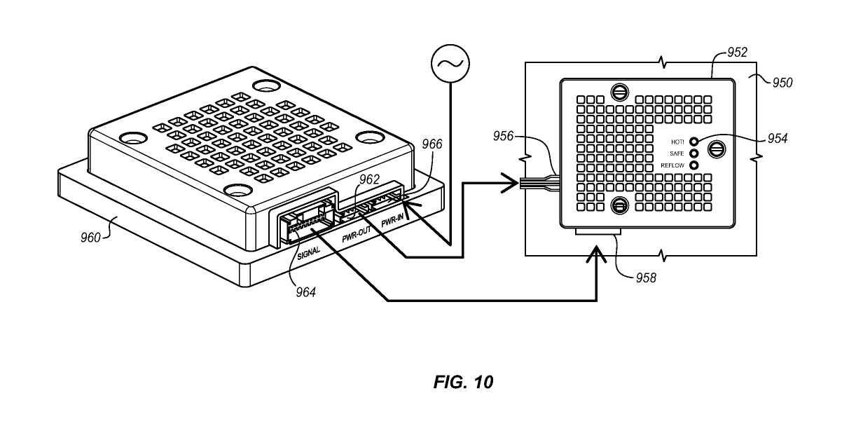

FIG. 10 is diagram of an external power module and interface module according to an embodiment.

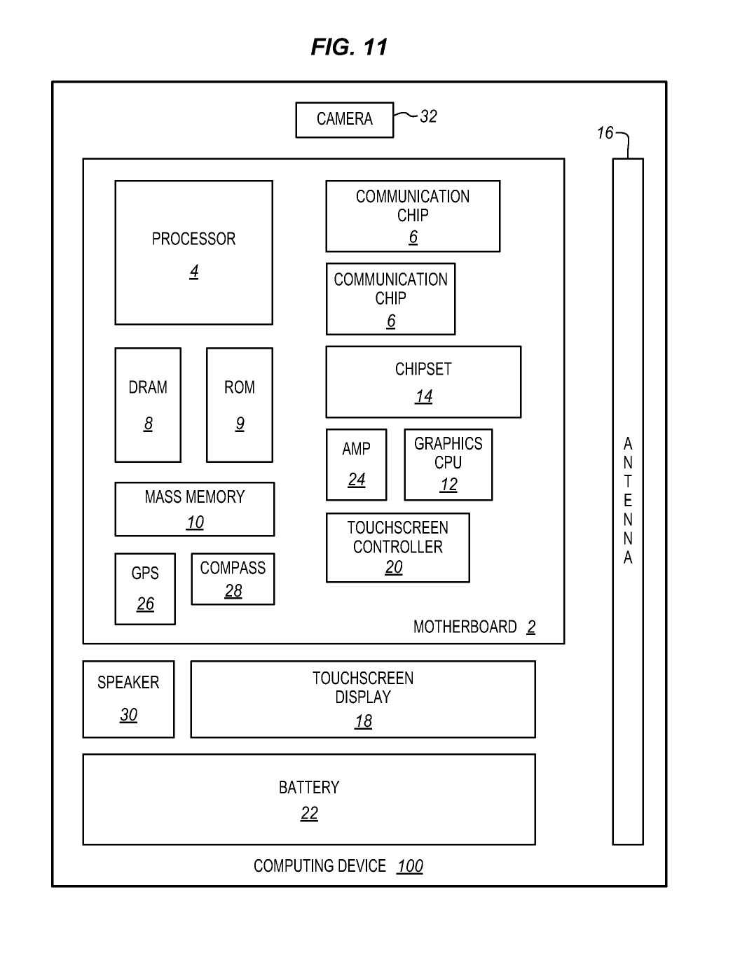

FIG. 11 is a block diagram of a computing device incorporating a tested semiconductor die according to an embodiment.

### DETAILED DESCRIPTION

As described herein, a direct solder connection can be formed on a circuit board that permits attachment and reattachment of a silicon chip component. The array of contacts may be formed directly on the circuit board. The component is then attached directly to the board with solder. This eliminates the LGA and MPI contacts for higher reliability, serviceability and signal integrity.

A heater is designed into the circuit board to reflow the solder and create a reliable solder joint. The control mechanism for the heater is provided in a reusable, modular device that can be used anywhere. This removes any dependency on factory tools. It also eliminates the expense of integrating the control circuitry integrated into every motherboard.

With the modular heater control circuit, a technician in the factory or field can install or replace a silicon chip component. The modular heater control circuit may be configured to use power from a motherboard or external source to drive the control and to drive the heater elements. The modular device may be configured to provide controlled current to a heater circuit to reflow the solder balls on the socket substrate. Features on the motherboard or a socket may be used to position the silicon chip component for reliable interconnection. When completed, the technician can remove and reuse the modular device.

FIG. 1 is an isometric exploded diagram of a component to be attached to a circuit board using a control module 100. A circuit board 106, such as a motherboard or a test fixture board has a connection grid 107 formed of lands or pads. Solder may be pre-applied to these lands for attaching the component 109. Heater traces (not shown) are formed on the motherboard around the contact points of the connection grid. When current is driven through the heater traces, the traces generate enough heat to melt solder connections to attach the component 109 to or remove the component from the motherboard. Instead of the lands or pads being formed directly on the motherboard, an interposer may be used. The interposer may be in the form of a socket, a multilayer circuit board, a silicon board, or any other suitable interposer may be used. With an interposer, the interposer is attached to the circuit board using surface mount or solder reflow technology. The component 109 is then attached to the interposer as described below. The interposer may contain all of the connectors to the component, the heater traces and routing layers to connect to the motherboard.

The component 109, which may be any silicon die or packaged device, is placed over the lands 107 on the circuit board 106. Any of a variety of different alignment features 108 may be attached to the circuit board to guide the component into correct alignment with the lands. In the illustrated example features, in this case alignment corners are provided to allow the component to float and self align to the pads The circuit board may be configured with wiring traces on the circuit board to connect the component through the lands to external components for test or for operation, depending on the implementation. There may also be resistors and other passive devices (not shown) to support the component, power supply lines and other devices attached to the circuit board.

The installation module is in the form of an assembly that includes its own controller board 101 mounted to a power chassis 110 that carries the controller board and other components 146 including the circuitry to control the heating process. The controller board carries active or passive components 146 or both to control the flow of current from the motherboard to heating elements on the motherboard. Pogo pins 102 are mounted to each corner of the chassis and extend through the controller board. In this case four pins are shown but more or fewer may be used or a different alignment system other than pogo pins may be used. The pogo pins interconnect the controller board to electrical connectors 112 on the circuit board. As shown, the electrical connectors are simple copper lands that connect to contacts on the pogo pins, however, any of a variety of other electrical connectors may be used. The pogo pins also serve as alignment pins to align the control module with the alignment features 108 on the circuit board, however, any of a variety of alignment schemes may be used. The pogo pins may be used to receive power from the motherboard and also to supply power to the heater traces. Alternatively, an external connection may be made for one or both of these functions.

A top plate 114 carries a switch 105 to control the operation of the control module. The top plate is mounted over and attached to the power chassis using flexible tabs 126 that snap into slots (not shown) and removable push rivets 103. The push rivets use springs to help lift the packaged device off the board during a removal process. The top plate covers the power chassis and all of the components for safety and to provide a comfortable gripping surface to hold and move the control module. The top cap 122, 124 allows the interposer to be gripped to extract the component when the component is removed.

A mode control switch 105 sets the control module for installation and removal. In this example, the mode control switch has beveled rounded surfaces to engage mating beveled surfaces on the top plate and connect the switch to the top plate. A connection post 122 connected to the power chassis extends through the top plate to also attach to the control switch. In this way, the control switch has a bayonet mount to the top plate and attaches also to the power chassis. This holds the top plate between the power chassis and the switch. The removable push rivets also hold the top plate to the power chassis. Alternatively, the top plate and power chassis may be fastened together in any of a variety of other ways.

Push rivets 116 are attached on each of two sides of the power chassis. The push rivets extend through the power chassis to contact the motherboard. The push rivets have springs 118 to hold a contact plate 110 away from the motherboard during normal use. The push rivets may be pushed down from above against the resistance of the springs to contact the motherboard and be pressed through connection holes 142 that are aligned in position with the push rivets. The push rivets latch into the holes to hold the power chassis in place until firmly pulled away to remove the push pins from the holes. A variety of attachment methods using standoffs, thumbscrews, or other tooled or tool less methods may also be used.

When removing a component, the heater traces may be activated to melt solder of a connection to the motherboard and the push rivet springs may be used to urge the component and the control module 124 up and away from the motherboard. Tabs on the bottom of the power chassis grip the component by the sides so that the component is pulled up by the control module. As shown, there is one push rivets on either of two opposite sides of the power chassis. There are two tabs for holding a component each on opposite side of the power chassis and on adjacent sides from the push rivets. The particular arrangement for the application of extraction forces and gripping features may be adapted to suit different components and different attachment configurations.

FIG. 2 is an isometric view of the control module 100 fully assembled and placed on a motherboard 106 over a component. The component is underneath the control module and is not visible in the figure. The top plate 114 is mounted over the power chassis 110 and prevents direct contact with electrical components on the power chassis. In one example, the component (not shown) 109 is snapped into place in the control module and held in position using the tabs 124. The control module is then placed over the motherboard using the alignment of the pogo pins 102 and the corner alignment features 112 on the motherboard. Once the control module is in place over the motherboard, the control module is used to solder the component to the motherboard.

The solder may be applied to the motherboard connection grid before the control module is moved into position. With the control module in place, the pogo pins establish an electrical connection from power pads on the motherboard into the control module. The power from the motherboard is provided by the control module to heater traces of the motherboard or an interposer of the motherboard.

The switch 105 of the control module 100 has two positions, remove at 12:00, install at 9:00. The install and remove positions of the switch activate or deactivate the springs that lift the part of the board during removal. The control module may have a variety of different programmed current or temperature cycles that are controlled by the integrated circuit components on the control circuit board. These cycles may be operated autonomously so that the user does not need to monitor the control module during a heating cycle. Alternatively, a simpler on, off switch may be used to control power to the heater traces.

A set of LEDs are used as a control interface for the control module. There is a first LED 130 used for “HOT.” This LED may be activated whenever the heater traces are powered in order to indicate that the system is at a dangerous or high temperature. There is a second LED labeled “SAFE.” This LED may be used to indicate that the control module is in position, connected to the motherboard and the component and that the temperature is safe for user to touch the control module. The third LED is labeled “REFLOW.” This LED may be continuous or flashing to indicate to the user that the soldering operation is in progress, and should not be interrupted in any way. While these three LEDs are sufficient for safe operation of the control module, there may be more or fewer, depending on the particular implementation. Other types of user outputs may be used instead of those shown. A more detailed display system may be used or the system may be configured for a remote display using wireless or wired connections to an operator terminal.

FIG. 3 is an isometric view of placing a heat sink over a silicon component using the mounting and alignment features described above. The silicon component 309 is attached to the printed circuit board 306 between a set of corner alignment features 308 as described above. The component is soldered in place using heater traces within an interposer board, the printed circuit board, or a socket depending on the particular implementation. FIG. 3 shows how the holes for the control module may also be used for normal heatsink attachment.

The heat sink 316 has a push pin 318 on at least two sides that connects into respective holes 312 in the motherboard. These are the same holes that were used to hold the control module in place. A thermal grease or other thermally conducing material is applied to the top of the component 309. The heat sink is then pressed against the top of component and the push pins are pressed until bottom pins 314 are pressed through the holes in the motherboard to hold the heat sink in place. The component may then be operated at high speeds and high loads without overheating. Such a heat sink mounting system may be used for test or normal operation purposes.

For a test fixture, after the testing is completed, the heat sink may be removed by pulling up on the push pins. The component may then be removed by reattaching the control module. A similar approach may be used to replace a silicon component in the field. While the heat sink is shown as a metal base with an array of metal heat fins, such as aluminum fins, the heat sink may take any of a variety of passive or active forms. A more precise heat sink, such as a liquid cooling system may be used to control the temperature of the component more precisely.

FIG. 4 is a top plan view of heater traces that may be used with the control module as describe herein. The heater traces may be formed in an interposer 400, such as interposer 107 of FIG. 1. Alternatively the heater traces may be formed directly on the circuit board 106 or in a socket. The heater traces are embedded into a material that is very close to the connection points that are to be soldered. In FIG. 4, there is an array of connection points 406 that are to be soldered to a component (not shown). The heater traces run in rows 404 and columns 402 between each of the connection points coming as close to the connection points as permissible by the thermal and design rules of the heater traces. When the heater traces are powered, they heat up, heating the printed circuit board that carries them and, through the board, heating the connection points of the array of lands on the circuit board.

The heater traces may be embedded into any suitable layer of the interposer, such as layer 2 of the interposer. The heater traces heat the vias in the interposer and, through the vias, heat the pads. The heater traces may be in any of the inner layers of the interposer that is able to heat the vias. In the example of FIG. 4 heat travels through the board material, into the vias and then into the surface mount solder pads. The particular configuration of the heater traces may be adapted to suit the flux type, flux application, and flux quantity. The flux provides a medium to transfer heat from the interposer board to the bottom of the component to be soldered.

FIG. 5A is a process flow diagram of installing a silicon component on a motherboard as described herein. Before the component can be installed, a connection point array with heater traces is provided. This may be done by building these features into the motherboard or, as described above, by constructing an FR4 (pre preg) interposer with a ball grid array (BGA) and routing layers between the BGA and land to attach to the motherboard. The interposer is installed on the motherboard when the motherboard is initially assembled or at any other time.

The process of FIG. 5 begins with preparing the system to use the control module described herein. Accordingly, the interposer is soldered onto the motherboard, test board, or other substrate at 502. As mentioned above, the interposer may be made of any of a variety of materials. On one side it is configured to connect to the motherboard. On the other side it is configured to be soldered to the silicon device component. The interposer also includes connection for the control module and heater elements near or even surrounding the connection pads, balls, or lands that connect to the component.

The interposer may be soldered to the mother board in a conventional manner. In addition at 504 any other components are soldered to the motherboard. The particular components will depend on the type of board and its intended use. These other components may include voltage regulators, power supplies, or other system components, such as memory, graphics, input/output hubs, and communication interfaces.

At 506, the component item that is to be installed is inserted onto the interposer. This may be done with the aid of the integrated corner alignment features shown, for example, in FIG. 1 or any other alignment or placement aid. The corner features ensure secure and proper alignment of the connection points on the component with those on the interposer.

At 508 the control module is positioned on the motherboard over the component. This can include aligning the pogo interconnect pins with the electrical connection points on the mother board. It can also include pressing the push rivets into respective holes on the motherboard to secure the push pins and the control module on the board or an alternate attachment method.

At 510, the control module is connected to a power source. This may be done by connecting the motherboard to power so that the control module is powered through the pogo pins, or it may be done by connecting a power source directly to the control module. With power connected, at 512, the operator selects the “install” mode using the mode control.

The control module then initiates a solder reflow cycle at 514. At 516 the control module applies current from the motherboard or another external source to the heater traces of the interposer. The traces heat through resistive heating and this heat propagates from the traces to the connection pads and solder that has been applied either to the interposer or the component.

As the on board controller of the control module energizes the heater elements in the interposer, it also monitors the temperature of the component to ensure that the component is within a temperature range for low temperature solder reflow. The control module regulates the current to the heater traces to maintain a desired temperature. This temperature is selected to be sufficient to reflow the solder without harming the component, the interposer or the connection array.

The particular temperature may be modified to suit different materials, different uses, and different types of connections. As an example, a lower temperature, less robust solder may be used for attachment to a test board because the tests will be run under carefully controlled conditions. For a product shipped to an end user, a more robust, higher temperature solder may be used to withstand the physical stress of shipping and operational temperature changes and also to last the many years desired for the end product. The solder compounds used on the interposer to the motherboard may also affect the choice of solder compound used to connect the interposer to the component. Using a lower temperature solder on the interposer to component joints may allow the lower temperatures solder to reflow without affecting the solder between the interposer and the motherboard.

At 520 a reflow indicator LED blinks. The control module may be fitted with a variety of different control and display systems. In the illustrated example a set of LEDs are used. In such an example, there may be a reflow LED to indicate that a reflow process is underway. When the reflow process ends, then this LED will turn off. Different blinking cycles may be used with all of the LEDs to indicate different levels for each status indication. At 522, the HOT indicator LED illuminates to indicate caution. The HOT indicator may be controlled directly by the measured or monitored temperature or by other conditions.

When the cycle ends, the reflow LED is turned off. The HOT LED may still indicate that the system is too hot to touch and that the solder is still cooling. When the temperature has reached a safe level, then the HOT led extinguishes at 524 and the SAFE LED illuminates at 526 to confirm that the reflow process is over. At this point the component is successfully connected to the interposer and is ready for test or operation depending on the implementation.

At 528 the operator removes the control module by pressing on the pogo pins and pulling the push pins out of their mating holes in the motherboard. At 530 a heat sink may optionally be attached to the component. A particular convenient attachment mechanism is shown in the example of FIG. 3. Other preparations may also be made and the motherboard with the installed component may be installed into a test or computing system for use.

FIG. 5B is a process flow diagram of attaching a component to a circuit board showing only operations of the control module. At 552 the control module receives a reflow enable signal. This signal may come from a positioning of the selector switch 105 if the control module is so equipped. Alternatively, the signal may come from any of a variety of other control systems, depending on the particular implementation of the operation of the control module. At 554 upon receiving the reflow enable signal, the control module initiates a reflow cycle. This cycle may be to connect or disconnect the component from the interposer. The control module may include an MCU (MicroController Unit) that contains various thermal profiles for different device types and for solder and desolder. The MCU may detect an appropriate profile from the interposer and control the current flow through the heater to create an appropriate temperature cycle to solder or desolder the component.

In the example of FIG. 2, the control module is attached to a circuit board and is placed over a silicon component. The control module and the component are placed over an interposer. The interposer is in turn connected to the circuit board. The interposer has contact pads to electrically connect to pads of the silicon component. After reflow the component and the interposer are soldered together. Alternatively, the control module melts the solder connection to allow the component to be removed.

At 556 the control module applies current from the control module to the heater connection terminals of the interposer. The heater connection terminals are coupled to resistive heater traces of the interposer. The heaters heat the solder on the contact pads of the interposer to reflow that solder either to make or break a solder connection. The current may be provided by a connection to the circuit board or from another external source.

At 558 the control module may activate a reflow indicator signal. There may be other signals such as a hot temperature warning, a specific temperature indication, a timer or any other desired signal. A small group of LEDs are shown herein, however, the indicator may be in other forms.

At 560, the control module completes the reflow cycle. As a result, at 562, the current application stops. This may be accompanied by extinguish the reflow indicator signal at 564, indicating a safe temperature or other indications. After the reflow cycle has ended, the control module may be removed. In addition, the component may be removed if the reflow cycle was for removing the component.

FIG. 6 is a process flow diagram of removing a component from an interposer board using the control module. As with installation, there is no reflow oven and there is not large equipment used. The component may be installed and removed using only the control module and a source of power that is sufficient to reflow the solder through the heater traces.

Component removal is similar to installation, except that the control module control is set to “remove.” This allows the springs that are coaxial with the pogo pins to exert upward pressure on the component. When the solder has melted enough to release the attachment between the component and the interposer, then the pressure of the springs serves to remove the component from the board.

Starting at 602 the heat sink, if one is present, is removed from the component. At the same time any other accessories or connections are removed from the top of the component. This allows access to the top of the component and at 604 the control module is positioned on the board over the component. As with installation, the pogo pins are connected to the power supply lands of the board and the push rivets are secured to the board.

With the control module attached and in place over the component at 606 the motherboard is connected to power source. The power source may optionally be connected before placing the control module or may simply remain in place.

At 608 an operator begins a remove process with the control module. This may be done in the illustrated example by rotating the selector to the remove mode position on the control module. The control module then initiates a reflow cycle at 610. Similar to installation, for the reflow process, the on board controller energizes the heater elements in the interposer at 612 and also monitors and regulates the temperature for solder reflow at 614.

The reflow indicator blinks at 616 during the process. The HOT LED also illuminates at 618 after the system has become hot from the heater elements. At 620 during the reflow process, in the illustrated example, the pogo pin springs exert an upward pressure on the component as the solder melts in order to remove the component from the board. The control module is physically connected to the component. In FIG. 1, tabs 124 reach under the component and grasp a part of the underside of the component. The upward pressure of the springs is transferred to the component through these tabs, so that the control module pulls upward on the component. When the solder is sufficiently melted, the solder connection is released and the springs pull the component away from the interposer connection array.

At 622 the reflow LED extinguishes after the component is released or after a timer has elapsed. The HOT LED extinguishes after the reflow cycle is completed and the system has cooled. The SAFE LED illuminates at 624 when the system is safe to touch.

The operator may then remove the control module at 626 and remove the component at 628. This may be done by lifting both off the motherboard as a single assembly. The component may then be released from the control module. The interposer connection array and the component connection array may then be cleaned at 630 of excess solder, rosin, or any other material. For a test system or to repair an operational system, the interposer is prepared for the installation of another component at 632. As an example, a cleaning pad may be installed in the control module, a cleaning cycle initiated. The pad may be used to remove any excess solder and prepare for the installation of a new component. In other cases, the interposer or the component or both may be replaced or discarded. Any preparation of the component or the interposer may be adapted to suit any particular implementation and used of the control module.

As shown the interposer requires very little additional space on the board compared to a surface mount connection. The interposer requires much less space than a socket. This increases flexibility for board designs. The interposer provides a more reliable and efficient connection than an MPI socket. The risk of factory and field damage during assembly or service that is common with LGA sockets is also eliminated.

The control module allows for the last minute configuration of parts, increasing efficiency and minimizing inventory management in a system factory. Additionally, the reworkable nature of the connection to the interposer allows an expensive CPU component to be reclaimed if it is installed on a defective board. The control module is also small and portable. This allows for the component to be replaced, for upgrade or repair on installed systems in the field. The system does not have to be returned to a remote factory or repair facility.

Using power supplied to the motherboard, the control module electrically enables solder reflow between the component and the interposer by providing a constant controlled power to, for example, a BGA (Ball Grid Array) heater. The control module includes circuitry to maintain the heater temperature. The temperature may be set by the motherboard or the temperatures may be set by a control module memory. This heater temperature may be set and changed using the control module at any time during the substrate solder ball reflow process.

FIG. 7 is a block diagram of a heater temperature control circuit 702. It includes a heater 704, in the form of the traces on the interposer, connected to a DC (Direct Current) voltage source 706 through a power MOSFET (Metal Oxide Semiconductor Field Effect Transistor) 708 and a current sensor 710. The current sensor signal is fed through an RC low-pass filter 712 to one of two inputs of an HC (Hysteretic Comparator) 714. The other HC input is coupled to a TSS (temperature set signal) 716, which sets the heater temperature.

The solder is melted under a thermal-balance condition, which is maintained in this example by closed loop control. The closed loop keeps the power delivered to the heater constant, regardless of the heater resistance. The control circuitry also incorporates an enable input 718 that is applied to a comparator 718. The enable comparator compares the enable input to the temperatures set signal and if both are active then the comparator output is provided to the power MOSFET 708. The enable input 718 is set by an external control switch, such as the reflow position of the rotary switch of the control module. The enable input activates the heater by activating the power MOSFET. This allows the control circuitry to regulate the heaters when a package replacement or a solder ball reflow process starts.

When the controlled circuit is enabled, the switching MOSFET turns on and the output capacitor of the RC-filter starts to be charged by the current sensor signal. Once the capacitor voltage crosses an upper hysteretic comparator threshold, set by the TSS, the hysteretic comparator turns the MOSFET off and the RC filter capacitor starts to discharge. As the capacitor voltage crosses a lower hysteretic comparator threshold, the HC turns the MOSFET on. The two thresholds set a temperature range for the reflow process. The MOSFET cycles on and off to maintain the desired heater temperature. After the preset temperature is reached the heater operates in a thermal-balance condition until the package removal or other reflow process is complete and the enable signal gets de-asserted.

Since the low pass filter output signal is proportional to the average current level from the MOSFET, the power generated in the heater, remains unchanged. The power delivered by the MOSFET to the heater is equal to a product of the constant input voltage and the average current consumed by the heater. Because the switching MOSFET dissipates very little power almost all of the power consumed from the input power source is supplied to the heater. In the ON state the voltage across the MOSFET is close to zero. In the OFF state current through the MOSFET is close to zero so the MOSFET dissipates very little power.

A variety of different temperature and current control and regulation systems may be used to provide current to the heater traces. More complex and simpler systems may be used. The example of FIG. 7 is provided only as an example. While in the example of FIG. 7, a single temperature is maintained during the reflow process, the temperature instead may be changed during the reflow process. The temperature may be increased according to a timing or temperature map. The temperature may be maintained or reduced in any desired pattern by changing the thresholds as desired. In another embodiment, the heater temperature can be controlled using closed loop switching. Different pulse width modulation (PWM) settings may be used to switch MOSFET duty cycle based on comparing a heater temperature sensor signal to a reference level.

The heater may be implemented in any of a variety of different ways. FIG. 4 shows a serpentine trace 402, 404 enveloping each contact pad 406 as it winds around a layer of the interposer without touching the contact pads. As shown the traces pass between and around the contact pads 406 of the interposer. The connection pads shown are those for connecting with the silicon device component.

To generate a required power level in the heater at a lower supply voltage and without using a boost regulator, the heater trace may be divided into N equal sections, which may be controlled jointly or individually, using one or more switches, to provide different temperatures in different heater domains. The resistance of each section may be described as Rₜ/N, where Rₜ is the total resistance of the heater trace and N is the number of sections. By connecting all of the heater sections in parallel for joint control, the equivalent heater resistance is N times lower than the resistance of each section. The equivalent heater resistance R_{tE}=Rₜ/N².

FIG. 8A shows an example of a resistive heater trace 806 with a total resistance of Rₜ, The heater has two heater terminal power connections 802, 804 to form a single continuous heater element.

In FIG. 8B, there is a terminal power connection 812 connected to two separate resistive heater trace sections 816, 818 in parallel. The two traces are both connected to a second power terminal 814 also in parallel. The two sections form an equivalent resistance R/2²=R/4. Similarly in FIG. 8C two heater terminal power connections 822, 824 are connected in parallel to three separate heater trace sections 826, 828, 830. This creates an equivalent resistance of R/3²=R/9. Dividing the heater trace into multiple sections and connecting them in parallel allows the same heater power to be generated at a lower supply voltage. The heat of a high voltage heater can be matched at a lower voltage. This allows reflow temperatures to be generated at voltage levels typically used for an electronics motherboard.

This principle can be shown, for example by comparing a high (V₁) voltage level and a low (V₂) voltage level and then setting the power to be equal:

P=V₁²/R_{tE}=(N²×V₂²)/Rₜ

Accordingly, the same power level achieved at V₂ may be achieved at V₁/N. As an example to generate 24 W power in an original heater trace with resistance Rₜ=24Ω, a 24 V voltage source V₁ is required. Dividing the heater trace into two equal sections and connecting the two sections in parallel, as shown in FIG. 8B reduces the necessary voltage. Consider a 12 V source as V₂. R_{tE}=Rₜ/N²=24/2²=6; P=V₂²/R_{tE}=12²/6=24 W.

By dividing the heater trace into equal sections and connecting them in parallel, as shown in FIGS. 8B and 8C, the voltage may be reduced. This allows the control circuitry size and cost to be reduced, increasing its efficiency by eliminating additional converters and using existing voltage sources available on the motherboard.

FIG. 9A is an isometric exploded diagram of an alternative control module and motherboard combination. A circuit board 902 has an interposer 904 attached to the circuit board using surface mount or solder reflow technology. A component 906 is then placed over the interposer. The interposer may contain all of the connectors to the component, the heater traces and routing layers to connect to the motherboard. In particular, the interposer has heater connections 920 to connect to pogo pins of the control module to independently drive each of the heater traces of the interposer. The component 906 is placed over lands on the interposer and held in place by an indexing feature, an adhesive or any other feature.

The circuit board 904 includes many other features (not shown) to support any of a variety of external components and to connect to power, data, I/O and other devices. The circuit board also includes alignment corners 912 to hold the interposer in position when attaching the interposer and also to help to align alignment pins 910 of a control module 932. In addition to the corners, the circuit board include three pegs 916 that engage three corresponding posts 918 on the control module. The posts are placed over the pegs to hold the control module in place.

The control module 932 has control circuitry 914 and a power connector 924 to receive power from an external supply. This received power may be used to run the control circuitry or to drive the heater traces of the interposer or both. A cover 926 covers the control circuitry and provides a user interface 928.

FIG. 9B is an isometric and cross-sectional diagram of the same control module in place over the component (not shown) and the interposer 904. The pogo pins 930 on one side are clearly visible and make and electrical connection from the control module circuitry to connectors on the interposer. In this example, the connections are directly to the heater traces of the interposer. However, the connections may alternatively be to the circuit board so that the circuit board make the connections to the heater traces. If the circuit board is used to supply power to the control module and to the heater traces, then it may be useful to connect the pogo pins to the circuit board. In this example, an external power connection 924 is provided from the control module, so that a direct connection to the heater traces is simpler but not necessary.

Analogous to inserting a processor into a socket, during repair or in a manufacturing flow a processor 906 is placed onto the interposer 904. Flux is applied by to the interposer. Alignment features on the interposer align the processor for correct soldering. The installation tool 932 containing the controller 914 is installed onto the board. The reflow cycle is initiated by the operator, and the profile runs, reflowing the processor to the board. The interposer is a part of the main motherboard build and already soldered onto the motherboard, although it could be attached a later time via a rework process. The processor is inserted into the interposer using alignment features by hand, or potentially via installation tool. The control module 932 is positioned on the board. Controller features mate to board features, and secure with screws or any suitable method. The board features may be heat sink mounting standoffs as shown in FIG. 3.

Install mode is selected on the control module by software or a mode switch. Reflow is then initiated in response by software or mode switch. During the reflow operation, the reflow indicator 928 blinks, the hot indicator tells the operator to wait, and then the safe indicator illuminates, to indicate that the module can be safely removed.

As the reflow indicator blinks, the control module sends an excitation current through the pogo pins to the heater traces. The heater traces begin to respond to the excitation current. Sensor traces also begin to heat in response to the increasing temperature of the heater traces.

The controller 914 provides a precision current to the sensor traces through others of the pogo pins. The sensor traces are aligned to the heater trace segments to allow for individual control of zones for better flexibility and for compensation of differences in motherboard copper density and layout. The sensor layer of the interposer allows for the accurate temperature measurement and closed loop control of the heater zones.

The controller 914 monitors the voltage, representing sensor trace average temperature, to control the heater current and ensure the proper temperature is attained to meet the solder reflow profile. The controller completes the profile, and manages any controller interface LED indicators 928. The heat sink assembly may be the final installation step.

FIG. 10 is a diagram of a simpler interface module 952 positioned over a component and interposer on a circuit board 950. The interface module is coupled to an external power module 960. The parts, layout, and arrangement shown in FIG. 10 is the same as that of FIGS. 9A and 9B, except the heater drive and control resides on an outside module 960. The controller assembly is within the power module 960, while the interface module 952 has interface boards that transfer the signals from cable connections to the pogo pins. In other words, the control module, described above, is divided into two separate components, a simpler interface component that fits on the circuit board, and an external intelligent component that connects to the interfaces using cables. Depending on space limitations and other demands, the external component may instead connect in other ways including directly over the interface component using direct physical connectors.

A power cable connector 956 is coupled to a power supply output 962 of the power module. The power supply output provides the heater drive current. A sensor signal output 958 of the interface module provides the sensor signals to a signal connector 964 of the power module. The signal connector of the interface module may also drive the user interface LEDs 954, and any other functional connections. An external power supply connector 962 of the power module receives an external DC power supply, or AC power supply to power the power module and provide power to feed to the heater traces and any components of the interface module 952. If the external power is AC, then a DC converter may be built into the power module.

With the implementation of FIG. 10, the control circuitry and power supply is from the external power module. The connections to the interposer and the user interface are in the interface module. The user interface may also be moved from the interface module to the power module. As shown and described in other embodiments, the control module is designed together with the motherboard so that it fits over the processor and the interposer and connects to the interposer. The control module and motherboard are also designed so that other parts on the motherboard do not interfere with the attachment, removal, and use of the control module. In the present example, instead of designing controllers to fit into the module that mounts on the board with the component, the external power module works with any component and printed circuit board combination by plugging into the simpler interface module that only provide connections, protection, alignment, and user indicators. The interface module is simpler to design and build because all of the control and power circuitry are removed.

FIG. 11 illustrates a computing device 11 in accordance with one implementation of the invention. The computing device 11 houses a board 2. The board 2 may include a number of components, including but not limited to a processor 4 and at least one communication chip 6. The processor 4 is physically and electrically coupled to the board 2. In some implementations the at least one communication chip 6 is also physically and electrically coupled to the board 2. In further implementations, the communication chip 6 is part of the processor 4.

Depending on its applications, computing device 11 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth). These components may be connected to the system board 2, mounted to the system board, or combined with any of the other components.

The communication chip 6 enables wireless and/or wired communications for the transfer of data to and from the computing device 11. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 11 may include a plurality of communication chips 6. For instance, a first communication chip 6 may be dedicated to shorter range wireless communications such as Wi-Fi and Bluetooth and a second communication chip 6 may be dedicated to longer range wireless communications such as GPS, EDGE, GPRS, CDMA, WiMAX, LTE, Ev-DO, and others.

The processor 4 of the computing device 11 includes an integrated circuit die packaged within the processor 4. In some implementations of the invention, the integrated circuit die of the processor, memory devices, communication devices, or other components include one or more dies that are tested or mounted with an interposer as described herein, if desired. The term “processor” may refer to any device or portion of a device that processes electronic data from registers and/or memory to transform that electronic data into other electronic data that may be stored in registers and/or memory.

In various implementations, the computing device 11 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 11 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to system having an interposer having a top side to connect to a silicon component and a bottom side to connect to a circuit board, the top side having a plurality of contact pads to electrically connect to the silicon component using solder, a plurality of heater traces in the interposer having connection terminals, and a removable control module to attach over the interposer and silicon component to conduct a current to the heater connection terminals to heat the heater traces, to melt a solder on the contact pads of the interposer and to form a solder joint between the component and the interposer.

Further embodiments include a temperature control circuit of the control module to control the current provided to the heater connection terminals. In further embodiments, the temperature control circuit comprises a comparator to compare a sensed temperature of the interposer to a threshold and to adjust the current to the heater connection terminals based on the comparison. The temperature control circuit comprises a power transistor coupled to the heater traces and wherein the comparator has a second input coupled to a current sensor signal so that the power transistor is switched on when the current sensor signal is below a selected voltage.

Further embodiments include an RC-filter between the current sensor signal and the comparator so that a capacitor of the RC-filter is charged by the current sensor signal and the power transistor is switched off after the RC-filter reaches a selected charge voltage.

In further embodiments the heater traces comprise a serpentine pattern of conductive traces that pass between contact pads of the interposer. The control module further comprises pins to removably physically connect the control module to the circuit board, the pins extending from the control module on at least two opposing sides of the component to connect to the circuit board. The pins connect to the circuit board by extending through and engaging holes formed in the circuit board.

In further embodiments the control module further comprises pogo pins to electrically connect with lands on the circuit board to conduct current from the circuit board to the control module. The control module further comprise pogo pins to electrically connect with lands on the interposer to conduct current from the control module to the heater connection terminals.

In further embodiments the control module further comprises a control switch to cause the control module start a solder reflow process by conducting current to the heater connection terminals. The control module further comprises a display to indicate whether the control module is operating a solder reflow process. The plurality of heater traces are connected in parallel to a single supply voltage.

Some embodiments pertain to a method including receiving a reflow signal at a control module, the control module being attached to a circuit board over a silicon component and over an interposer, the interposer being connected to the circuit board, the interposer having contact pads to electrically connect to pads of the silicon component, initiating a reflow cycle of the control module, applying current from the control module to heater connection terminals of the interposer, the heater connection terminal being coupled to resistive heater traces of the interposer to reflow solder on the contact pads of the interposer, and stopping the application of current upon the completion of the reflow cycle.

Further embodiments include activating a reflow indicator signal upon initiating the reflow cycle. Further embodiments include activating a hot indicator signal after initiating the reflow cycle and activating a safe indicator signal after completing the reflow cycle. In further embodiments applying current comprises applying current from the circuit board to the interposer through the control module. Further embodiments include regulating the applied current to maintain a predetermined reflow temperature of the interposer.

Some embodiment pertain to an apparatus including an electrical connector to receive power from an external supply, an electrical connector to drive heater traces of an interposer to heat solder connections and attach a component to the interposer, an electrical connector to receive thermal sensor signals to determine a temperature of the solder connections, a user interface to receive a command to initiate a solder process and to indicate that the solder process is finished, and a controller to receive the command, to apply the received power to the heater traces in response thereto, to control the applied heater power based on the received thermal sensor signals to drive a solder reflow profile in the solder connections, and to power the user interface to indicate that the solder process is finished.

In further embodiments, the apparatus removably attaches to a printed circuit board to drive the solder reflow process and to press the component against the circuit board.

1.-20. (canceled)

21. An apparatus comprising:
an interposer having a top side to connect to a silicon component and a bottom side to connect to a circuit board, the top side having a plurality of contact pads to electrically connect to the silicon component using solder;
a plurality of heater traces in the interposer having connection terminals; and
a removable control module to attach over the interposer and silicon component to conduct a current to the heater connection terminals to heat the heater traces, to melt a solder on the contact pads of the interposer and to form a solder joint between the component and the interposer.

22. The apparatus of claim 21, further comprising a temperature control circuit of the control module to control the current provided to the heater connection terminals.

23. The apparatus of claim 22, wherein the temperature control circuit comprises a comparator to compare a sensed temperature of the interposer to a threshold and to adjust the current to the heater connection terminals based on the comparison.

24. The apparatus of claim 23, wherein the temperature control circuit comprises a power transistor coupled to the heater traces and wherein the comparator has a second input coupled to a current sensor signal so that the power transistor is switched on when the current sensor signal is below a selected voltage.

25. The apparatus of claim 24, further comprising an RC-filter between the current sensor signal and the comparator so that a capacitor of the RC-filter is charged by the current sensor signal and the power transistor is switched off after the RC-filter reaches a selected charge voltage.

26. The apparatus of claim 21, wherein the heater traces comprise a serpentine pattern of conductive traces that pass between contact pads of the interposer.

27. The apparatus of claim 21, wherein the control module further comprises pins to removably physically connect the control module to the circuit board, the pins extending from the control module on at least two opposing sides of the component to connect to the circuit board.

28. The apparatus of claim 27, wherein the pins connect to the circuit board by extending through and engaging holes formed in the circuit board.

29. The apparatus of claim 21, wherein the control module further comprises pogo pins to electrically connect with lands on the circuit board to conduct current from the circuit board to the control module.

30. The apparatus of claim 29, wherein the control module further comprise pogo pins to electrically connect with lands on the interposer to conduct current from the control module to the heater connection terminals.

31. The apparatus of claim 21, wherein the control module further comprises a control switch to cause the control module start a solder reflow process by conducting current to the heater connection terminals.

32. The apparatus of claim 31, wherein the control module further comprises a display to indicate whether the control module is operating a solder reflow process.

33. The apparatus of claim 21, wherein the plurality of heater traces are connected in parallel to a single supply voltage.

34. A method comprising:
receiving a reflow signal at a control module, the control module being attached to a circuit board over a silicon component and over an interposer, the interposer being connected to the circuit board, the interposer having contact pads to electrically connect to pads of the silicon component;
initiating a reflow cycle of the control module;
applying current from the control module to heater connection terminals of the interposer, the heater connection terminal being coupled to resistive heater traces of the interposer to reflow solder on the contract pads of the interposer; and
stopping the application of the current upon the completion of the reflow cycle.

35. The method of claim 34, further comprising activating a reflow indicator signal upon initiating the reflow cycle.

36. The method of claim 34, further comprising activating a hot indicator signal after initiating the reflow cycle and activating a safe indicator signal after completing the reflow cycle.

37. The method of claim 34, wherein applying current comprises applying current from the circuit board to the interposer through the control module.

38. The method of claim 34, further comprising regulating the applied current to maintain a predetermined reflow temperature of the interposer.

39. An apparatus comprising:
an electrical connector to receive power from an external supply;
an electrical connector to drive heater traces of an interposer to heat solder connections and attach a component to the interposer;
an electrical connector to receive thermal sensor signals to determine a temperature of the solder connections;
a user interface to receive a command to initiate a solder process and to indicate that the solder process is finished; and
a controller to receive the command, to apply the received power to the heater traces in response thereto, to control the applied heater power based on the received thermal sensor signals to drive a solder reflow profile in the solder connections, and to power the user interface to indicate that the solder process is finished.

40. The apparatus of claim 39, wherein the apparatus removably attaches to a printed circuit board to drive the solder reflow process and to press the component against the circuit board.
